(19) United States
(12) Patent Application Publication
(10) Pub. No.: US 2016/0300659 A1
(43) Pub. Date: Oct. 13, 2016

(54) POWER MODULE AND POWER CONVERTING DEVICE USING THE SAME

(71) Applicant: Delta Electronics (Shanghai) Co., Ltd., Shanghai (CN)

(72) Inventors: Yu ZHANG, Shanghai (CN); Shou-Yu HONG, Shanghai (CN); Hao-Yi YE, Shanghai (CN); Jian-Hong ZENG, Shanghai (CN)

(21) Appl. No.: 15/080,548

(22) Filed: Mar. 24, 2016

(30) Foreign Application Priority Data
Apr. 10, 2015 (CN) 201510171122.1

(51) Int. Cl. H01F 27/28; H01F 27/24; H05K 1/18

(52) U.S. Cl. CPC H01F 27/28; H05K 1/181; H01F 27/24; H05K 2201/10053

(57) ABSTRACT

A power module includes a magnetic component and a switch component. The magnetic component includes a magnetic core, and a winding disposed in the magnetic core. An end of the winding forms a pin of the power module for electrically connecting to an external circuit. The switch component is electrically connected to the magnetic component. An I/O pin of the power module may be formed from an end of the winding, such that a bonding/contact resistance of connecting the power module to the external circuit can be reduced.

### RELATED APPLICATIONS

This application claims priority to Chinese Application Serial Number 201510171122.1, filed Apr. 10, 2015, which is herein incorporated by reference.

### BACKGROUND

1. Field of Invention

The present invention relates to a power module and a power converting device.

2. Description of Related Art

Power modules which are characterized with high power density and high conversion efficiency are widely applied to system main boards for communication, data centers, etc. With the continuous improvement of levels of design and production, a progressively increasing number of transistors can be accommodated in an integrated circuit. The increase of the number of the transistors in the integrated circuit brings a more powerful computing capability, but at the same time the power consumption requirement of the circuit is significantly increased. The power of the power module thus needs to be continuously increased to cope with the demand of load correspondingly.

Since the space resource allocated to the power module by the system main board is limited, the requirement of power density of the power module is also continuously increased. As shown in FIG. 1A, a conventional power module 10 may fix a power component 20/magnetic component 22 to a circuit board 40, and then supply power to a load through bonding pins 30 of the power module 10 to a target main board 50. Because the power component 20/magnetic component 22 and the circuit board 40 are independent components, connections need to be performed through bonding by using solder 25. Such connections will cause additional bonding/contact resistances, such as R1, R2, R3 in FIG. 1B. Under the circumstances of high current output, losses caused by the bonding/contact resistances cannot be ignored.

For the forgoing reasons, there is a need to solve the above-mentioned problem by providing a power module and a power converting device using the same.

### SUMMARY

One aspect of the present invention provides a design to integrate a magnetic component and a pin so as to minimize a bonding/contact resistance. At the same time, the requirement of a high power density is satisfied to fulfill the continuously increasing requirements of high power, high current, high power density, and high performance.

According to one aspect of the present invention, a power module is provided. The power module includes a magnetic component and a switch component. The magnetic component includes a magnetic core and a first winding disposed in the magnetic core. A first end of the first winding forms a pin of the power module for electrically connecting to an external circuit which is disposed out of the power module. The switch component is electrically connected to the magnetic component.

One end of the winding of the magnetic component of the power module according to one aspect of the present invention can directly serve as the input/output pin of the power module. For example, the input/output pin of the power module is formed from the winding. As a result, the bonding/contact resistance can be effectively reduced.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A and FIG. 1B are a cross-sectional schematic diagram and an equivalent circuit schematic diagram of a power module of prior art, respectively;

FIG. 2 to FIG. 4 are exploded views of power modules according to various embodiments of this invention;

FIG. 5 and FIG. 6 are cross-sectional schematic diagrams of power converting devices according to various embodiments of this invention;

FIG. 7 to FIG. 10 are local circuit diagrams of systems when power modules according to the present invention are applied in various embodiments; and

FIG. 11 and FIG. 12 are exploded views of magnetic components of power modules according to various embodiments of this invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

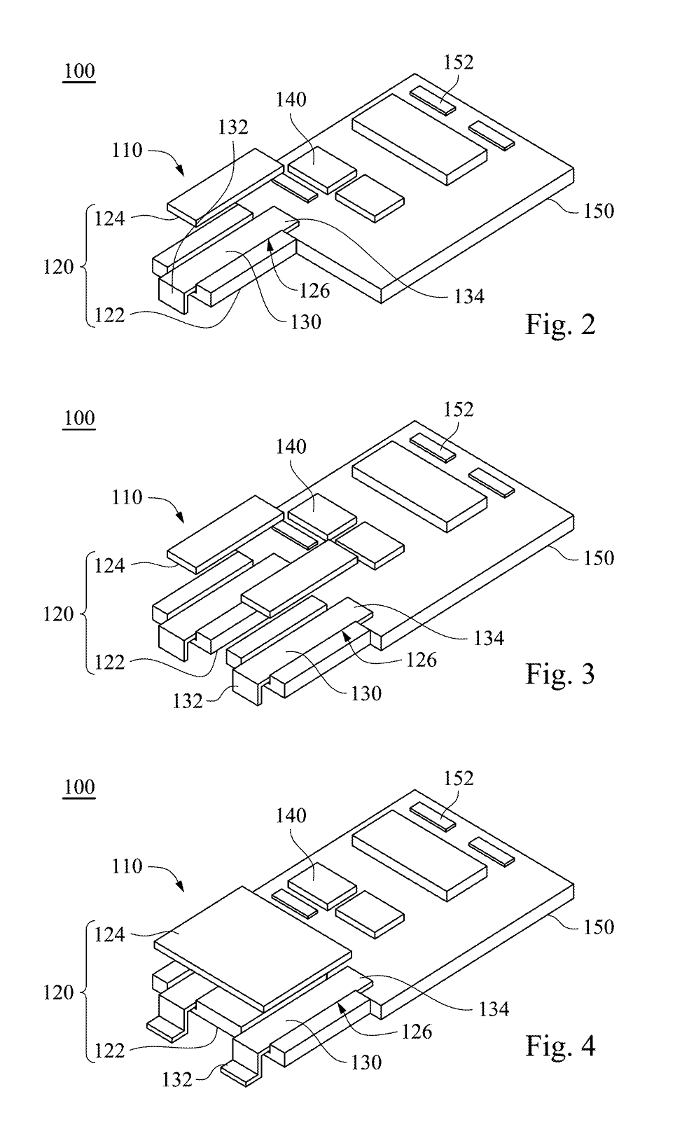

A description is provided with reference to FIG. 2. FIG. 2 is an exploded view of a power module according to one embodiment of this invention. A power module 100 comprises a magnetic component 110, a switch component 140, and a functional circuit board 150. The magnetic component 110 comprises a magnetic core 120 and a winding 130 disposed in the magnetic core 120. One end 132 of the winding 130 forms a pin of the power module 100 for directly electrically connecting to an external circuit which is out of the power module 100. Another end 134 of the winding 130 may also form a pin for connecting the functional circuit board 150, but the present invention is not limited in this regard. The switch component 140 is disposed on the functional circuit board 150 and is electrically connected to the magnetic component 110 via the functional circuit board 150, but the present invention is not limited in this regard.

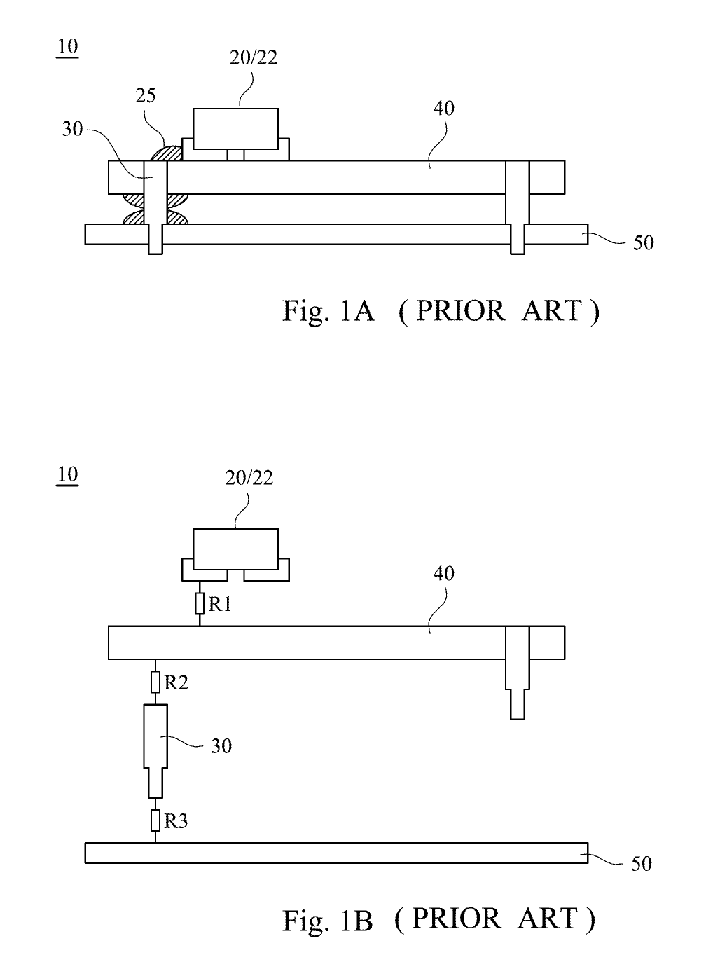

According to the present embodiment, the magnetic component 110 directly utilizes the winding 130 to serve as the pin so as to directly electrically connect to the external circuit which is out of the power module 100. The end 132 of the winding 130 forms an input end or an output end of the power module 100. For example, the external circuit can be a power source, and the end 132 of the winding 130 can be an input end to input the power into the power module 100. The additional pins and the solder for connecting the additional pin and the power component 20/magnetic component 22 shown in FIG. 1A can thus be omitted. The magnetic component 110 may contain or not contain structures like a bobbin, but the present invention is not limited in this regard. Such a design may reduce a bonding/contact resistance when the power module 100 is used so as to reduce a loss when the power module 100 is used.

In greater detail, the magnetic component 110 comprises the magnetic core 120 and the winding 130. The magnetic core 120 may comprise a lower cover plate 122 and an upper cover plate 124, and a passage 126 is defined between the lower cover plate 122 and the upper cover plate 124. The winding 130 is placed in the passage 126. However, the present invention is not limited in this regard. The preset invention may also adopt configuration structures formed by magnetic cores in other structures, such as an EE-shaped magnetic core. The winding 130 may have a first end 132 and a second end 134. The first end 132 may directly serve as the pin of the power module, and the second end 134 may be connected to the functional circuit board 150. The switch component 140 may be electrically connected to the magnetic component 110 via the functional circuit board 150.

In some embodiments, a number of the magnetic component 110 is one, a number of the passage 126 between the lower cover plate 122 and the upper cover plate 124 is one, and a number of the winding 130 corresponding to the passage 126 is also one, but the present invention is not limited in this regard. The magnetic core 120 and the passage 126 in the magnetic core 120 may be approximately in a rectangular shape, or may be in other shapes. An extending length of the winding 130 may be greater than a length of the magnetic core 120, such that the first end 132 of the winding 130 is exposed from the magnetic core 120 to serve as the pin so as to electrically connect to an external circuit. But the present invention is not limited in this regard. For example, a length of the winding 130 may be equal to the length of the magnetic core 120 and may be used for patch connection.

The functional circuit board 150 may be a carrier board, such as a printed circuit board (PCB), a direct copper bonding substrate, etc. A passive element, such as a resistor, a capacitor, etc., may be further disposed on the functional circuit board 150. The magnetic component 110 may serve as a magnetic element, such as an inductor or a transformer. The magnetic core 120 may be made of permanent magnetic material. The winding 130 may be sheet metal, such as a copper sheet. The winding 130 may also be, for example, a metal wire. In other embodiments, the winding 130 may be made of different kinds of conductive materials, such as cooper, silver, aluminum, graphite, etc. The winding 130 may be made by various methods, such as stamping, electroplating, or in a form of a lead wire frame, but the present invention is not limited in this regard.

Numbers of the magnetic components 110, the magnetic cores 120, and the windings 130 of the power module 100 can be varied depending on different design requirements. As shown in FIG. 3, the number of the magnetic components 110 of the power module 100 is two, and the two magnetic components 110 disposed on the functional circuit board 150 are independent of each other. Each of the magnetic components 110 has a passage 126. The windings 130 are disposed in each of the passages 126. The first end 132 and the second end 134 of each of the windings 130 may be respectively exposed from the magnetic core 120. Each of the magnetic components 110 is connected to the functional circuit board 150 via the second end 134. The first ends 132 serve as the pins of the power module 100.

As shown in FIG. 4, the number of the magnetic component 110 of the power module 100 is one, and the magnetic component 110 has the magnetic core 120 and the two windings 130. In other words, the two passages 126 are defined between the lower cover plate 122 and the upper cover plate 124 of the magnetic core 120. The two windings 130 are respectively disposed in the two passages 126. However, the present invention is not limited in this regard. For example, a number of the passage(s) may be one or plural, such as three. Similarly, the first end 132 and the second end 134 of each of the windings 130 may be respectively exposed from the magnetic core 120.

The windings 130 may be the flat windings shown in the figure, or wound windings. The first end 132 of each of the winding 130 forms the pin of the power module 100. The first end 132 of each of the windings 130 may further have a pin portion for better connecting and fixing performance. The pin portion may be formed by deforming the first end 132, as shown in FIG. 4. For example, the pin portion and the winding 130 may be integrally formed. Under the circumstances, a configuration of the pin portion and the winding 130 may be varied depending on the design. Or, some other implementation method may be adopted, for example, the pin portion may be formed by bending the winding 130. Under the circumstances, configurations and shapes of pin portion and the winding 130 may be different due to reprocessing. However, the present invention is not limited in this regard.

The first end 132 of the winding 130 may be connected to the external circuit in a straight plug manner. At this time, the first end 132 may be bent downwards vertically from the magnetic core 120 one time, as shown in FIG. 2 and FIG. 3, so as to serve as a direct insert process (DIP) pin. A cross-sectional area of the pin portion may be larger than, equal to, or smaller than cross-sectional areas of other portions of the winding 130, and the cross-sectional shape of the pin portion may be square, rectangular, round, trapezium, ring circle or other shapes. The first end 132 of the winding 130 may also be connected to the external circuit in a surface patching manner, as shown in FIG. 4. Namely, the first end 132 of the winding 130 can be regarded as a surface mount technology (SMT) pin. After the first end 132 is bent downwards from the magnetic core 120 one time, the first end 132 is bent horizontally one time so as to serve as an SMT pin. However, the present invention is not limited in this regard.

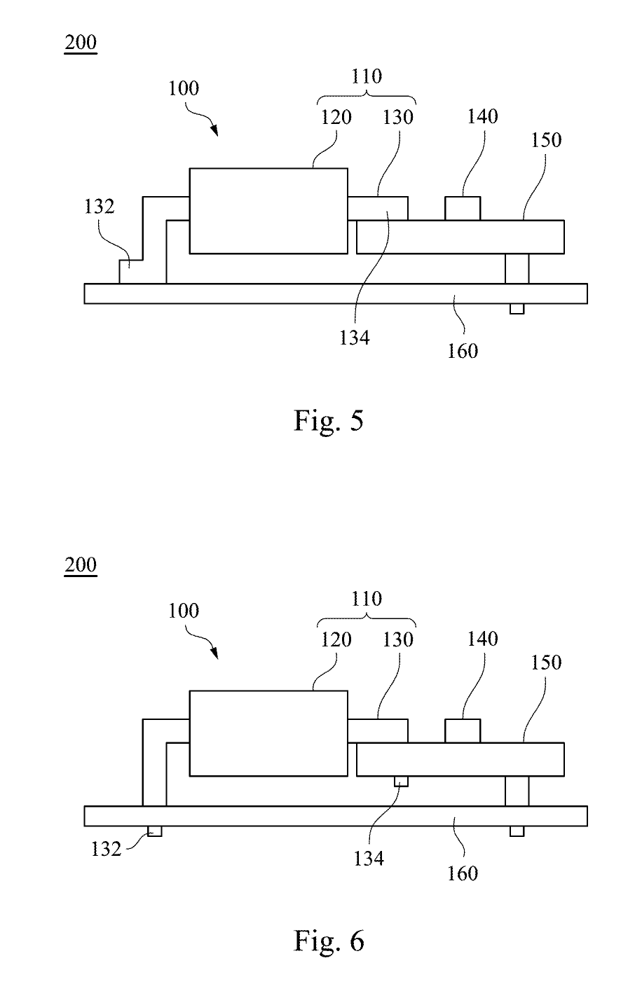

Then, a description is provided with reference to FIG. 5. FIG. 5 is a cross-sectional schematic diagram of a power converting device according to one embodiment of this invention. A power converting device 200 comprises the above power module 100 and a system circuit board 160. The power module 100 is disposed on the system circuit board 160. The system circuit board 160 can be seen as an external circuit, but the invention is not limited in this regard. The power module 100 comprises the functional circuit board 150, and the switch component 140 is disposed on the functional circuit board 150. The magnetic component 110 is electrically connected to the switch component 140 via the functional circuit board 150. The magnetic component 110 comprises the magnetic core 120 and the winding 130. The winding 130 has the first end 132 and the second end 134 which may be opposite to each other. The first end 132 forms the pin of the power module 100. The first end 132 can be fixed and electrical connected to the system circuit board 160. The first end 132 and the second end 134 are directly electrically connected to the system circuit board 160 and the functional circuit board 150 respectively, so as to avoid extra bonding/contact resistance.

According to the present embodiment, the second end 134 of the winding 130 is fixed and electrical connected to the functional circuit board 150 in a surface patching manner. The second end 134 can be fixed to the functional circuit board 150 by using solder, but the present invention is not limited in this regard. The first end 132 of the winding 130 may also be connected to the system circuit board 160 in a surface patching manner. The first end 132 can be fixed to the system circuit board 160 by using solder. Since the pin portion is formed by bending the winding, the pin portion and the winding 130 can be integrally formed, but the present invention is not limited in this regard, the pin portion and the winding 130 can be made separately. As compared with the embodiment according to the prior art (as shown in FIG. 1A), the present embodiment can omit an additional and independent pin used for connecting the magnetic component and the system circuit board, and omit solder for connecting the independent pin and the magnetic component/system circuit board. The power module 100 may further include a housing(not drawn), the external circuit is disposed out of the housing on the system circuit board 160, and the first end 132 of the winding 130 forms an input end or an output end of the power module 100 and the first end 132 is located out of the housing.

A description is the provided with reference to FIG. 6. FIG. 6 is a cross-sectional schematic diagram of a power converting device according to another embodiment of this invention. The difference between the present embodiment and the previous embodiment is that the first end 132 and the second end 134 of the winding 130 according to the present embodiment are connected to the system circuit board 160 and the functional circuit board 150 in a straight plug manner, but the present invention is not limited in this regard. In greater detail, the functional circuit board 150 and the system circuit board 160 have connecting holes. The first end 132 and the second end 134 of the winding 130 can form pin portions to be inserted into the plug holes. Then, the first end 132 and the second end 134 of the winding 130 are respectively fixed to the system circuit board 160 and the functional circuit board 150 by, for example, using solder. However, the present invention is not limited in this regard. For example, the second end 134 may also be connected to a pin of a conventional bobbin.

The first end 132 and the second end 134 of the winding 130 of the power module 100 may be combinations of a DIP pin (such as by bending once in FIG. 3) and an SMT pin (such as by bending twice in FIG. 4). The first end 132 and the second end 134 of the winding 130 may both be DIP pins or SMT pins. Or, the first end 132 and the second end 134 of the winding 130 may respectively be a DIP pin and an SMT pin. However, the present invention is not limited in this regard.

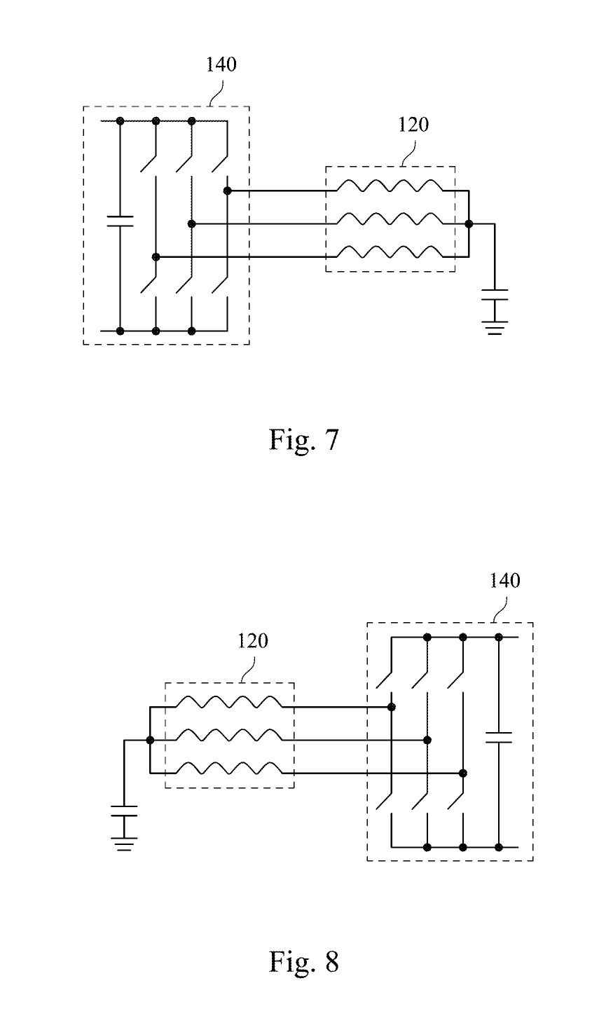

The magnetic component 110 of the above power module 110 may be an inductor, as shown in FIG. 7 and FIG. 8. FIG. 7 and FIG. 8 are local circuit diagrams of power modules according to various embodiments of this invention. As shown in FIG. 7, the power module comprises a buck circuit, for example, the power module may be a structure in which three buck circuits are connected in parallel. The inductors in the buck circuit can be the above-mentioned magnetic component. Output terminals of the three inductors are connected to an output capacitor. An output terminal where the three inductors are connected together can be an output terminal of the power module 100. That is, the output terminal of the inductors may also serve as an output terminal of a circuit, but the present invention is not limited in this regard. In FIG. 7, the three inductors may be made independent of one another, but of course they may be made coupled to one another. The three buck circuits may be connected in parallel and operate in a same phase. Or, the three buck circuits may operate with a specific phase shift, such as a phase shift of 120 degrees, to reduce ripples on the output capacitor. Hence, various embodiments of the magnetic components in the above power module 100 can be adopted.

The power module comprises a boost circuit in FIG. 8. FIG. 8 is a structure in which three boost circuits are connected in parallel. The inductors in the boost circuit may be the above-mentioned magnetic component. Input terminals of the three inductors are connected to an input terminal of the power module, that is, the windings of the magnetic components serve as input pins of the power module, but the present invention is not limited in this regard. Similarly, the three inductors may be made independent of one another or coupled to one another. The three circuits may be connected in parallel and operate in a same phase. Or, the three circuits may be connected in parallel and operate with a phase shift. The input terminals of the inductors may serve as a partial input terminal of the power module to be directly connected to the system circuit board so as to reduce the conduction loss of the circuit. In addition, various embodiments of the magnetic components in the above power module 100 can be adopted.

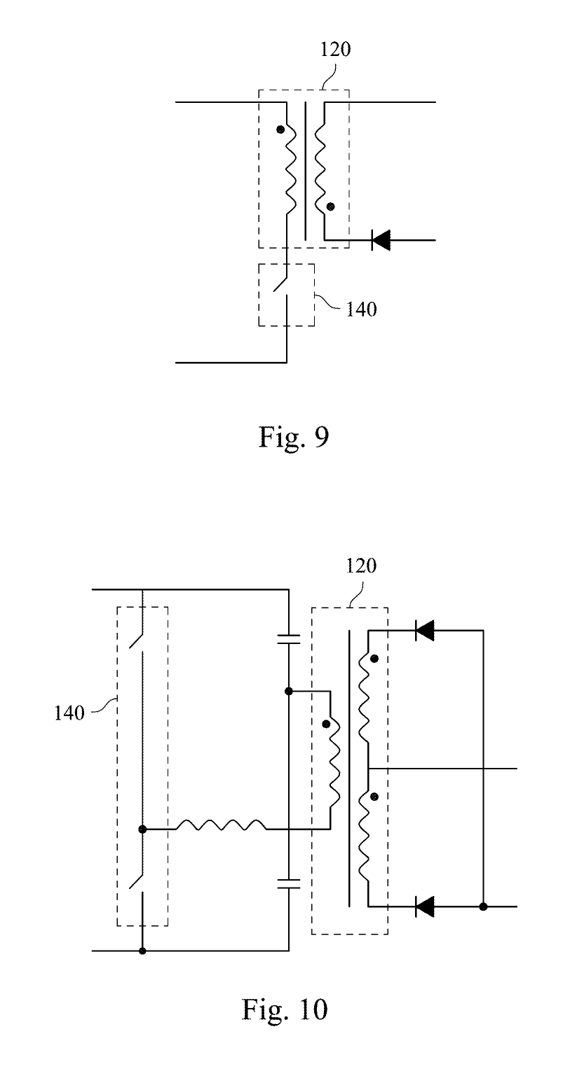

The magnetic component 110 of the above power module 100 can also be applied to a transformer, as shown in FIG. 9 and FIG. 10. FIG. 9 and FIG. 10 are local circuit diagrams of power modules according to other various embodiments of this invention. As shown in FIG. 9, the power module comprises a flyback transformer circuit. Or, as shown in FIG. 10, the power module comprises an LLC transformer circuit. In these transformer circuits, the magnetic component can serve as a transformer or a component of a transformer. The power module may use two ends of the secondary winding as output pins. However, the present invention is not limited in this regard, and various embodiments of the magnetic components in the above power module 100 can be adopted.

When the magnetic component serves as the transformer, a primary winding, the secondary winding, or combinations thereof may adopt the above-mentioned windings in inductors, but the present invention is not limited in this regard.

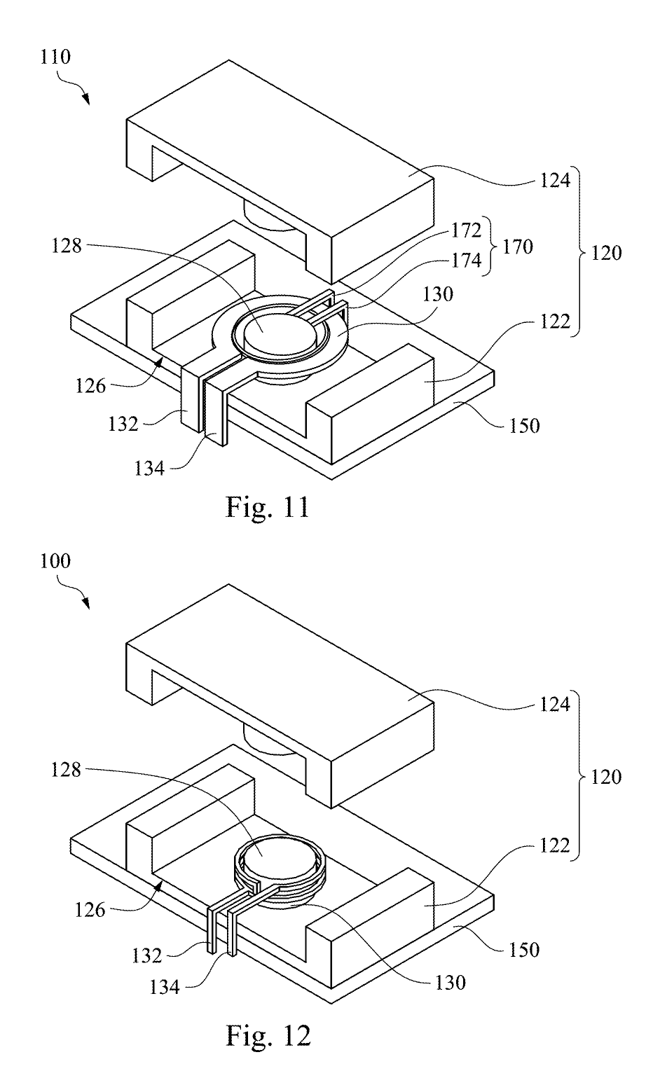

FIG. 11 and FIG. 12 are exploded views of magnetic components of power modules according to various embodiments of this invention. The magnetic component 110 is disposed on the functional circuit board 150. The magnetic component 110 comprises the magnetic core 120 and the winding 130. The magnetic core 120 comprises the lower cover plate 122 and the upper cover plate 124. A passage 126 is defined between the lower cover plate 122 and the upper cover plate 124. Each of the lower cover plate 122 and the upper cover plate 124 may further have a center column 128, but the invention is not limited in this regard. The center columns 128 are disposed in the passage 126. The winding 130 sleeves the center column 128. A number of the windings may be plural, and the plurality of windings may have different shapes, wire diameters, or numbers of turns, etc., but the present invention is not limited in this regard. As shown in FIG. 11, the winding 130 and a winding 170 may sleeve the same center column 128 in the magnetic component 110. The first end 132 and the second end 134 of the winding 130 according to the present embodiment may extend from a same side of the magnetic component 110, and both the first end 132 and the second end 134 can directly serve as input/output pin(s) of the power module. Two ends 172, 174 of the winding 170 can be connected to the functional circuit board 150. The winding 130 and 170 may be primary and secondary windings respectively. Each of the plurality of windings may be a metal sheet (as shown in FIG. 11), or a wound wire (as shown in FIG. 12), etc. A first end and a second end of each of the plurality of windings may be connected to the external circuit in a surface patching manner or in a straight plug manner, but the present invention is not limited in this regard.

In summary, as compared with the prior art in which the additional and independent pins are used to connect the power module and the external circuit, one end of the winding of the magnetic component of the power module according to the present invention can directly serve as the input/output pin of the power module. As a result, the bonding/contact resistance can be effectively reduced.

Although the present invention has been described in considerable detail with reference to electrically connect certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A power module comprising:
a magnetic component comprising a magnetic core and a first winding disposed in the magnetic core, a first end of the first winding forming a pin of the power module for electrically connecting to an external circuit which is disposed out of the power module; and
a switch component electrically connected to the magnetic component.

2. The power module of claim 1, wherein the magnetic core comprises an upper cover plate and a lower cover plate, and the first winding is disposed in a first passage defined by the upper cover plate and the lower cover plate.

3. The power module of claim 2, wherein the upper cover plate and the lower cover plate further define at least one second passage, the magnetic component further comprises at least one second winding, wherein the at least one second winding is disposed in the at least one second passage.

4. The power module of claim 1, further comprising a functional circuit board, wherein the switch component is disposed on the functional circuit board, and a second end of the first winding is fixed and electrically connected to the switch component via the functional circuit board.

5. The power module of claim 1, wherein the power module comprises a buck circuit, or a boost circuit, or a flyback transformer circuit, or an LLC transformer circuit.

6. The power module of claim 1, wherein the first end of the first winding has a pin portion.

7. The power module of claim 6, wherein the pin portion of the first winding is a DIP pin or an SMT pin.

8. The power module of claim 6, wherein the pin portion of the first winding is exposed from the magnetic core.

9. The power module of claim 6, wherein the pin portion and the first winding are integrally formed.

10. The power module of claim 6, wherein the pin portion is formed by bending the first winding once to form a DIP pin, or the pin portion is formed by bending the first winding twice to form an SMT pin.

11. The power module of claim 6, wherein a cross-sectional shape of the pin portion is square, or rectangular, or round, or trapezium, or ring circle.

12. The power module of claim 1, wherein the first winding is a metal sheet or a wound wire.

13. The power module of claim 1, wherein magnetic components is an inductor, or a transformer.

14. The power module of claim 1, wherein the power module further comprises a housing, wherein the external circuit is disposed out of the housing, and the first end of the first winding forms an input end or an output end of the power module and is located out of the housing.

15. A power converting device comprising the power module of claim 1.

16. The power converting device of claim 15, further comprising a system circuit board, wherein the power module is disposed on the system circuit board, and the first end of the first winding is fixed and electrically connected to the system circuit board.

17. The power converting device of claim 16, wherein the power module further comprises a functional circuit board, wherein the switch component is disposed on the functional circuit board, and a second end of the first winding is fixed and electrically connected to the functional circuit board.
